(19) United States
(12) Patent Application Publication
(10) Pub. No.: US 2004/0012457 A9
(43) Pub. Date: Jan. 22, 2004

(54) Internal impedance match in integrated circuits

(76) Inventors: Mehdi Frederik Soltan, Stanford, CA (US); Hamid Reza Rategh, Cupertino, CA (US)

Correspondence Address: N.R.H. Black, dba Baypatent, 420 Miramontes Ave., Half Moon Bay, CA, 94019, US

(21) Appl. No.: 10/025,437

(22) Filed: Dec. 18, 2001

(51) Int. Cl. H03H 7/38

(52) U.S. Cl. 333/33; 333/247

(57) ABSTRACT

The invention relates to inductors in integrated circuits. Methods and apparatuses for semiconductor circuits and microcircuits that include on-chip inductive elements which may form general impedance blocks are disclosed.

### TECHNICAL FIELD OF THE INVENTION

The invention relates generally to ICs (integrated circuits). The invention more particularly relates to inductors in integrated circuits.

### BACKGROUND

CMOS (complementary metal-oxide semiconductor) technologies are well established and are used mostly for digital circuitry. However, they are also used for analog circuits, especially RF (radio frequency) circuits and hybrid circuits (both analog and digital circuitry on a single die).

RF designs often need RLC (Resistance, Inductance, Capacitance) circuit blocks. It is advantageous to incorporate circuits in their entirety on semiconductor chips as opposed to, for example, using off-chip discrete components. Capacitors fabricated on a semiconductor die (so-called “on-chip caps”) perform well. However, previously developed embodiments of on-chip inductors have been constructed using spiral shaped conductive traces on the die, these occupy valuable semiconductor die real estate and also such inductors typically have a poor Q factor. Thus there is a need for a superior on-chip inductors.

In RF circuits there is often a need to match impedances, this need is particularly great for power amplifiers where amplifier output stage and load must preferably be well matched for efficiency, reliability and other important performance parameters. To the buyer of single chip amplifiers, for example, it is desirable that the amplifier be well matched to the load(s) envisioned. Since there may be external constraints on the load design it is desirable for a single chip that includes a RF power amplifier to be pre-matched to the expected load. In impedance matching circuits a low insertion loss is typically desirable and this tends to require high Q inductive and capacitive components. Thus there is a need for single chip RF amplifiers that include on-chip output stage matching with good efficiency and hence low loss.

U.S. Pat. No. 6,046,640 issued 4 Apr. 2000 to inventor Brunner discloses the use of the inductance of a chip bondwire as part of a load. The present invention shows how bondwires can be specifically created to serve other purposes.

### SUMMARY OF THE INVENTION

The invention includes methods and apparatuses for semiconductor circuits and microcircuits that include on-chip inductive elements to form general impedance blocks. This may find application in various modes, for example, impedance matching the output stage of a RF power amplifier to a hypothetical load. Other examples may include intrastage matching in analog circuits, input stage impedance matching, tuned circuits for oscillators, analog filters, pre-selectors for RF receivers, and arbitrary impedance generation for test or measurement. More examples are possible within the general scope of the invention.

According to an aspect of the invention an integrated circuit comprises an amplifier formed on a semiconductor die and a bondwire electrically connecting the output port of the amplifier to an external conductor wherein the bondwire operates to match impedances.

According to a further aspect of the invention, a method for impedance matching comprises forming an amplifier on a semiconductor die and connecting an electrically conducting bondwire between the output port of the amplifier and an external conductor.

According to a further aspect of the invention methods for forming inductors, autotransformers and transformers on integrated circuits are disclosed. Integrated circuits formed by such methods are also disclosed.

### BRIEF DESCRIPTION OF DRAWINGS

FIG. 1 is an elevation (sectional) view drawing of part of an IC mounted on a PCB (printed circuit board) according to an embodiment of the invention.

FIG. 2 is a plan view of part of the IC of FIG. 1.

FIG. 3 is an elevation view of part of an IC according to an embodiment of the invention.

FIG. 4 is a plan view of part of the IC of FIG. 3.

FIG. 5 is an equivalent circuit of an exemplary embodiment of part of an IC represented by FIG. 4 according to an embodiment of the invention.

FIG. 6A is a plan view of part of an alternative exemplary embodiment of the invention.

FIG. 6B is an equivalent circuit of the part of an alternative exemplary embodiment of the invention of FIG. 6A.

For simplicity in description, identical components are labeled by identical numerals in this document.

### DETAILED DESCRIPTION

In the following description, for purposes of clarity and conciseness of the description, not all of the numerous components shown in the schematic are described. The numerous components are shown in the drawings to provide a person of ordinary skill in the art a thorough enabling disclosure of the present invention. The operation of many of the components would be understood and apparent to one skilled in the art.

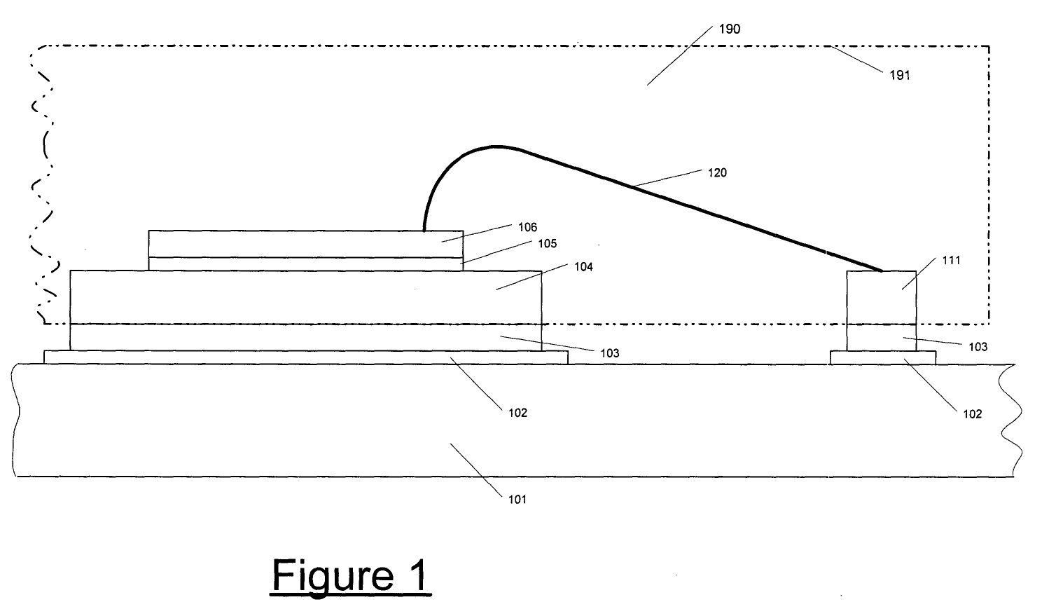

FIG. 1 is an elevation (sectional) view drawing of part of an IC 190 mounted on a PCB (printed circuit board) 101 according to an embodiment of the invention. The IC 190 may be formed as a substantially cuboid package, the boundaries of which are indicated by the pecked lines 191 in FIG. 1. The cuboid form is not critical and other forms of package are possible. The PCB 101 may bear metal (typically copper or copper alloy) conducting traces and/or mounting pads 102. The IC 190 may be electrically and/or mechanically joined to the traces or mounting pads 102 by conductive paste 103 by well known surface mounting techniques or otherwise.

The body or package of the IC 190 may typically be largely composed of non-conductive sealant or filler typically formed late in the manufacturing process, for example, by a molding or ceramic technique. The IC 190 may also contain an optional metallic thermal pad 104 which, if present, is typically formed of a good conductor of heat (such as gold), and a semiconductor die 106 which may be bonded to the thermal pad 104 by a die attach compound or glue 105. The semiconductor die is typically a silicon chip with various electronic components created therein by processes well known in the semiconductor industries. Many other processes for semiconductor dies, for example, GaAs HBT, MESFET and so on are well known in the arts and may be used within the general scope of the invention.

Still referring to FIG. 1, the IC 190 may also comprise a plurality of periphery pads 111 that are typically fabricated from noble metal such as gold. If optional metallic thermal pad 104 is present, it will typically be fabricated from the same metal as periphery pads 111. Periphery pads 111 may also be joined to the metallic traces or mounting pads 102 by paste 103. Several or all periphery pads 111 are electrically joined to die 106 by bondwires 120 which are typically formed of noble metal or metals such as gold or gold alloy.

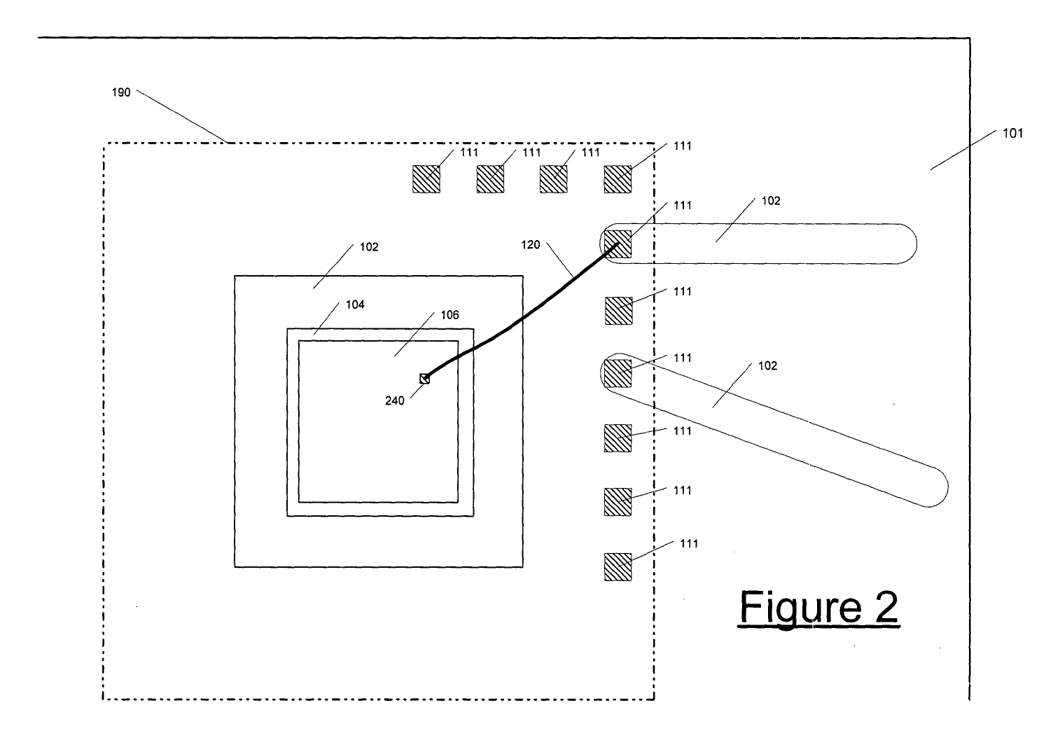

FIG. 2 is a plan view of part of the IC 190 and PCB 101 of FIG. 1. Shown are some of the plurality of periphery pads 111, some of the conducting traces or mounting pads 102, die 106, die attach or glue 104 and bondwire 120. Also shown is metallization pad 240 that may be formed into die to provide a conductive landing place for bondwire 120. Bondwires may be electrically and mechanically mounted by methods that are well known in the art.

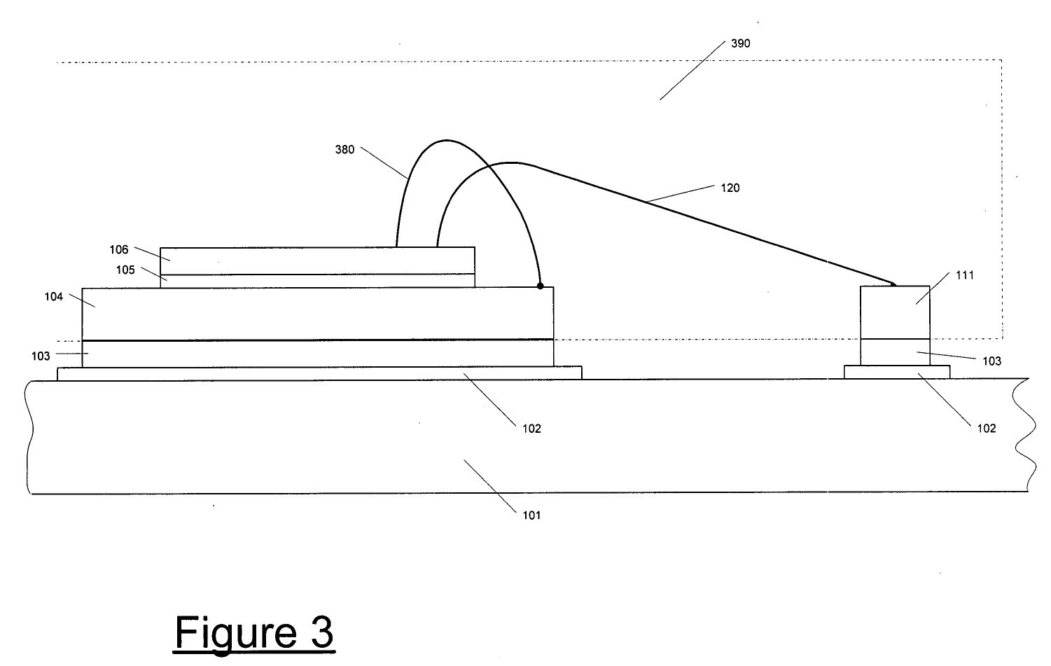

FIG. 3 is an elevation view of part of an IC 390 according to an embodiment of the invention. As contrasted with the elevation view of FIG. 1, an additional feature is present in the form of a bondwire 380 connecting die 106 to thermal pad 104. In an embodiment, thermal pad 104 is electrically connected as a conducting groundplane and is a component taken into account when RF (radio frequency) circuits are designed for embodiment, in part or whole, as micro-circuitry on semiconductor die 106.

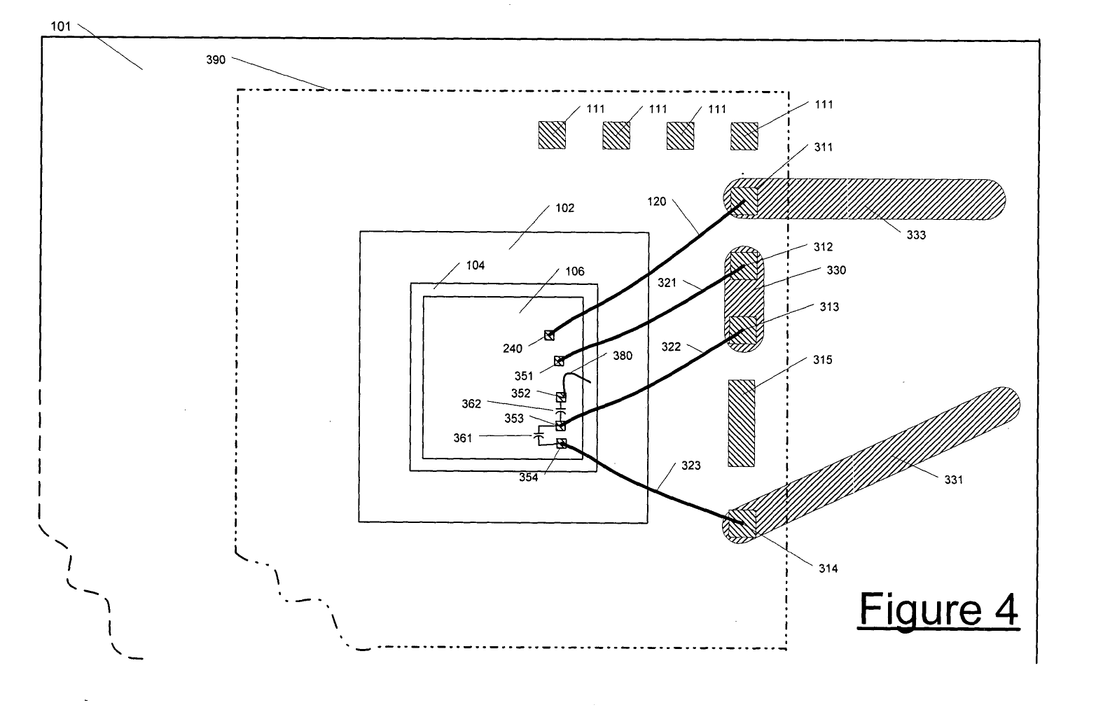

FIG. 4 is a plan view of part of the IC 390 of FIG. 3. Metallization pad 240 and bondwire 120 are shown electrically connecting die 106 via periphery pad 311 to metallic conductor 333 which may be an instance of conducting traces or mounting pads 102. Conductor 333 may be connected to a DC (direct current) power supply (not shown). Bondwire 380 electrically connects metallization pad 352 on die 106 with thermal pad 104. Other bondwires 321, 322 and 323 are shown connecting metallization pads 351, 353 and 354 respectively to periphery pads 312, 313 and 314 respectively. Conductor 330 electrically connects periphery pad 312 to periphery pad 313. Conductor 331 may provide an output signal port. On-chip silicon capacitors shown schematically as 361 and 362 may be provided to provide a signal path between metallization pads as shown in FIG. 4 or otherwise. Metallization pads and on-chip silicon capacitors are well known in the art. Periphery pads need not all be of the same geometry, for example, over-sized periphery pad 315 is shown. Also it is permitted to bond more than one bond wire to a single periphery pad. If multiple bondwires are to be bound to a single periphery pad, it use of an over-sized periphery pad, such as 315, may facilitate fabrication. However, two (or more) bondwires may also be bonded to a single, regular sized, periphery pad if necessary. Due to the geometries involved, one particular pad may be chosen over another to receive a particular bondwire on account of considerations such as bondwire length of position and resulting electrical properties. Typically pads placed at the corners of a chip will receive longer bondwires than pads in the middle of a side.

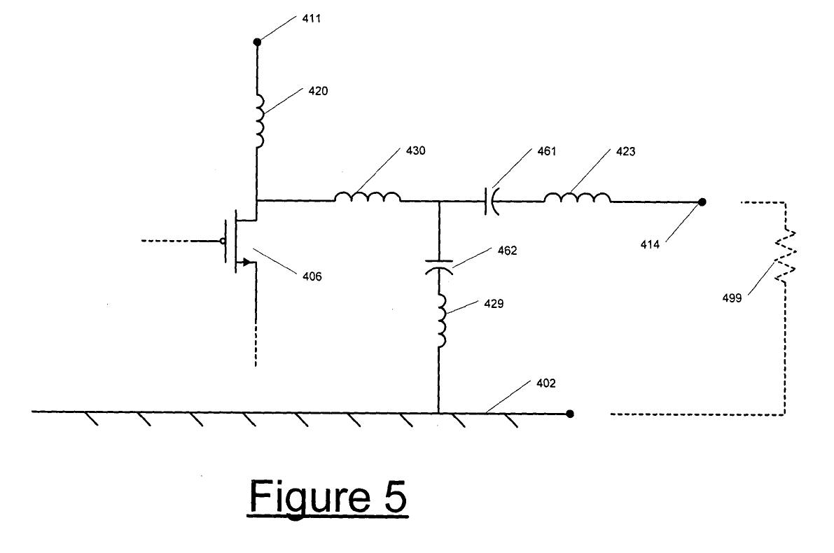

FIG. 5 shows an equivalent circuit of an exemplary embodiment of part of an IC 390 represented by FIGS. 3 and 4 according to an embodiment of the invention. Possible resistor 499 shown in pecked lines in FIG. 5, presents a real (i.e. zero phase angle) RF load external to the IC and connected at the output port 414.

Port 411 may be connected to a DC power supply (not shown). The remainder of the circuit, shown in solid lines) represents an output transistor 406, an internal inductive load 420 for transistor 406, a groundplane 402 and an impedance matching network formed by reactive components 429, 430, 462, 461 and 423. Matching networks to transform impedances to match an output stage to the characteristic impedance of a transmission line or the impedance of a load are well known in the art and may be embodied using reactive components in any of various topologies.

In the exemplary design of FIGS. 3, 4, and 5 a correspondence exists between equivalent circuit components and physical features of the IC 390. Referring then to both FIG. 4 and FIG. 5, groundplane 402 may be embodied as thermal pad 104. Similarly, inductive load 420 may be embodied conductor 333 and bondwire 120 in series thus providing a self-inductance. Inductance 430 may be embodied as bondwire 321 in series with conductor 330 and bondwire 322, again utilizing the self-inductance of the components. Capacitors 461 and 462 may be embodied as on-chip silicon capacitors 361 and 362 respectively. Inductance 429 may be embodied using the self-inductance of bondwire 380 and inductance 423 may be embodied using the self-inductance of bondwire 323 in series with conductor 331.

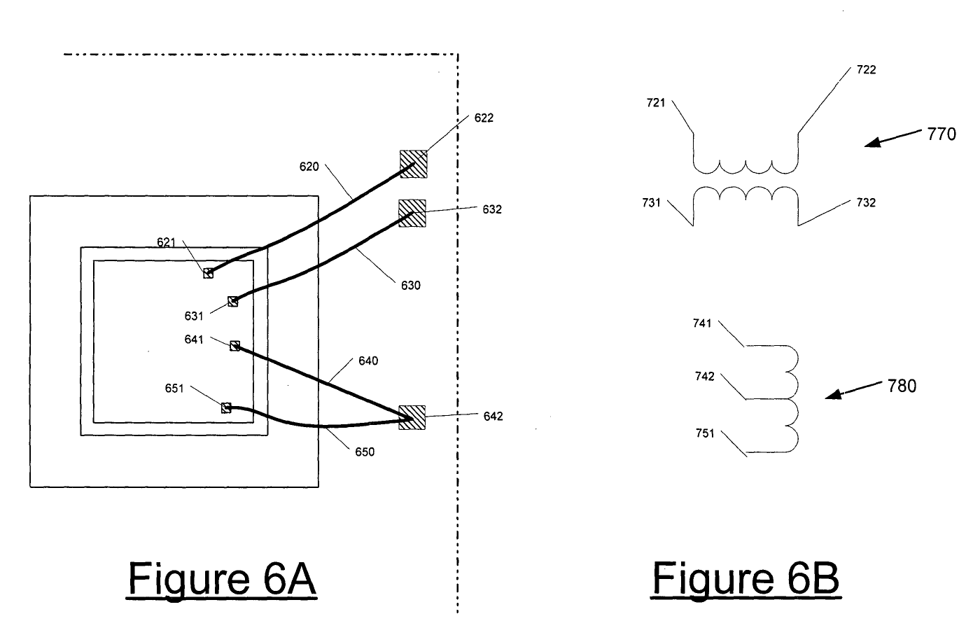

FIG. 6A a is a plan view of part of an alternative exemplary embodiment of the invention. Bondwires 620, 630, 640 and 650 connect metallization pads 621, 631, 641 and 651 to periphery pads 622, 632 and 642 as shown. The mutual inductances of bondwires 620 and 630 operate to form a 1:1 isolation transformer shown as equivalent circuit component 770 in FIG. 6B. Pads 621, 622, 631 and 632 (FIG. 6A) correspond to equivalent nodes 721, 722, 731 and 732 (FIG. 6B) respectively. Similarly, the mutual inductances of bondwires 640 and 650 operate to form an autotransformer shown as equivalent circuit component 780 (FIG. 6B). Pads 641, 642, 651 (FIG. 6A) correspond to circuit nodes 741, 742, 751 (FIG. 6B) respectively. Use of transformers and autotransformers in RF circuits, both for impedance matching and other purposes, is well known in the arts. Transformers and autotransformers created using bondwires may typically have lower losses and better linearity than components formed on-chip by old methods such as metallized traces.

The embodiments described with reference to FIGS. 3, 4, 5, 6A and 6B are exemplary only, and many other comparable configurations will be apparent to one of ordinary skill in the art. In particular a matching circuit could be embodied partly on-chip and partly off-chip, for example, using discrete components mounted on a PCB. In addition to adaptations, a number subsets of the circuits disclosed have utility. For example, an inductor formed from two bondwires could be connected to an on-chip capacitor to form a tank circuit.

Embodiments of the invention as described herein have significant advantages over previously developed implementations. As will be apparent to one of ordinary skill in the art, other similar circuit arrangements are possible within the general scope of the invention. For example, a different type of packaging may be used for the semiconductor using a lead frame and through hole pins rather the surface mounting. As a further example, although the use of MOS (metal-oxide semiconductor) dies have been described, the invention is applicable to numerous other semiconductor and integrated circuit technologies such as silicon bipolar, junction field effects transistor technologies, Gallium Arsenide and so on. The embodiments described above are intended to be exemplary rather than limiting and the bounds of the invention should be determined from the claims.

What is claimed is:

1. An integrated circuit comprising:
an amplifier formed on a semiconductor die, the amplifier having an output port with an output impedance; and
a bondwire electrically connecting the output port to an external conductor;
wherein the bondwire has a specified self-inductance and is operable to match the output impedance to a desired load impedance.

2. The integrated circuit of claim 1 wherein:
the amplifier is a radio frequency power amplifier.

3. The integrated circuit of claim 1 wherein:
the semiconductor die is a metal-oxide semiconductor die.

4. The integrated circuit of claim 1 wherein:
the semiconductor die is a gallium arsenide semiconductor die.

5. The integrated circuit of claim 1 wherein:
the semiconductor die is a bipolar semiconductor die.

6. A method for impedance matching comprising:
forming an amplifier on a semiconductor die, the amplifier having an output port with an output impedance; and
connecting an electrically conducting bondwire between the output port and an external conductor;
wherein:
the bondwire has a specified self-inductance and is operable to match the output impedance to a desired load impedance.

7. The method of claim 6 wherein:
the amplifier is a radio frequency power amplifier.

8. An integrated circuit comprising:
an amplifier formed on a semiconductor die, the amplifier having an output port with an output impedance;
a bondwire having a specified self-inductance and electrically connecting the output port to an external conductor; and
a capacitor having a specified capacitance formed on the semiconductor die and electrically connected between the output port and a ground, wherein:
the bondwire and the capacitor are operable to match the output impedance to a desired load impedance.

9. The integrated circuit of claim 8 wherein:
the amplifier is a radio frequency power amplifier.

10. The integrated circuit of claim 8 wherein:
the bondwire, the capacitor and the desired load impedance are jointly operable to resonate at a normal operating frequency of the integrated circuit.

11. The integrated circuit of claim 8 wherein:
the semiconductor die is a metal-oxide semiconductor die.

12. The integrated circuit of claim 8 wherein:
the semiconductor die is a gallium arsenide semiconductor die.

13. The integrated circuit of claim 8 wherein:
the semiconductor die is a bipolar semiconductor die.

14. A method for impedance matching comprising:
forming an amplifier on a semiconductor die, the amplifier having an output port with an output impedance;
connecting an electrically conducting bondwire having a specified self-inductance between the output port and an external conductor;
forming a capacitor having a specified capacitance on the semiconductor die and electrically connected between the output port and a circuit ground, wherein:
the bondwire and the capacitor are jointly operable to match the output impedance to a desired load impedance.

15. An integrated circuit comprising:
an amplifier formed on a semiconductor die, the amplifier having an output port with an output impedance;
a first bondwire having a first specified self-inductance, and electrically connecting the output port to a first external conductor;
a second bondwire having a second specified self-inductance, and electrically connecting the first external conductor to a node on the die;
a first capacitor having a first capacitance formed on the semiconductor die and electrically connected between the node and a ground;
a second capacitor having a second capacitance embodied on the semiconductor die and electrically connected between the node and a third bondwire, the third bondwire having a third specified self-inductance and electrically connecting the second capacitor to a second external conductor
wherein:
the first, second and third bondwires and the first and second capacitors are operable to match the output impedance to a desired load impedance.

16. The integrated circuit of claim 15 wherein:
the amplifier is a radio frequency power amplifier.

17. The integrated circuit of claim 15 wherein:
the first capacitor is connected to ground via a further bondwire.

18. The integrated circuit of claim 15 wherein:
the further bondwire connects to a thermal pad formed within the integrated circuit.

19. An integrated circuit comprising:
a semiconductor die;
a first bondwire having a first self-inductance electrically connected to the die and to an external conductor;
a second bondwire having a second self-inductance electrically connected to the die and to the external conductor, wherein:
the first and second bondwires are operable to act as an inductor to form at least a part of a circuit block comprised within the integrated circuit.

20. The integrated circuit of claim 19 wherein:
the circuit block is an analog circuit.

21. The integrated circuit of claim 19 wherein:
the circuit block is a radio frequency circuit.

22. The integrated circuit of claim 19 wherein:
the circuit block is selected from a list consisting of.
an intra-stage match, an input stage match, a tuned circuit, an oscillator, a filter, and a pre-selector for a radio receiver.

23. The integrated circuit of claim 19 further comprising:
a further bondwire connected between the die and a ground.

24. The integrated circuit of claim 19 further comprising:
a further bondwire connected between the die and a thermal pad.

25. An integrated circuit comprising:
a semiconductor die;
a first bondwire electrically connected to the die and a periphery pad;
a second bondwire electrically connected to the die and the periphery pad, wherein:
the first and second bondwires are operable to act as an autotransformer to form at least a part of a circuit block comprised within the integrated circuit.

26. An integrated circuit comprising:
a semiconductor die;
a first bondwire electrically connected to the die and a first periphery pad;
a second bondwire electrically connected to the die and a second periphery pad, wherein:
the first and second periphery pads are electrically connected, and
the first and second bondwires are operable to act as an autotransformer to form at least a part of a circuit block comprised within the integrated circuit.

27. An integrated circuit comprising:
a semiconductor die;
a first bondwire electrically connected to the die and a first periphery pad;
a second bondwire electrically connected to the die and a second periphery pad, wherein:
the first and second bondwires are operable to act as a transformer to form at least a part of a circuit block comprised within the integrated circuit.

28. A method for creating a passive component within an integrated circuit comprising:
connecting a bondwire between a semiconductor die and a periphery pad wherein the bondwire is operable to act as an inductor forming at least a part of a circuit block comprised within the integrated circuit.

29. The method of claim 28 further comprising:
connecting a further bondwire between the semiconductor die and the periphery pad.

30. A method for creating a passive component within an integrated circuit comprising:
connecting a first bondwire between a semiconductor die and a first periphery pad;
connecting a second bondwire between a semiconductor die and a second periphery pad electrically connected to the first periphery pad;
wherein the bondwires are jointly operable to act as an autotransformer forming at least a part of a circuit block comprised within the integrated circuit.

31. A method for creating a passive component within an integrated circuit comprising:
connecting a first bondwire between a semiconductor die and a first periphery pad;
connecting a second bondwire between a semiconductor die and a second periphery pad;
wherein the bondwires are jointly operable to act as a transformer forming at least a part of a circuit block comprised within the integrated circuit
